(19) United States
(12) Patent Application Publication
(10) Pub. No.: US 2006/0189080 A1
(43) Pub. Date: Aug. 24, 2006

(54) Method for fabricating semiconductor device

(75) Inventors: Min-Suk Lee, Chungcheongbuk-do (KR); Sung-Kwon Lee, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/363,811

(22) Filed: Feb. 27, 2006

(30) Foreign Application Priority Data
Feb. 28, 2005 (KR) 2005-0016845
Jun. 15, 2005 (KR) 2005-0051372
Feb. 21, 2005 (KR) 2006-0016820

(51) Int. Cl. H01L 21/336

(52) U.S. Cl. 438/261

(57) ABSTRACT

A method for fabricating a semiconductor device is provided. The method includes: forming at least two gate patterns over a substrate; forming a first sidewall layer over on entire of the substrate structure including gat patterns; forming an insulation layer over the first sidewall layer; selectively removing the insulation layer between the gate patterns to form a contact hole partially exposing the first sidewall layer; forming a second sidewall layer over the first sidewall layer exposed by the contact hole; and removing the first and the second sidewall layers disposed at a bottom portion of the contact hole to expose a selected portion of the substrate between the gate patterns.

### FIELD OF THE INVENTION

The present invention relates to a method for fabricating a semiconductor device; and, more particularly, to a method for forming a contact plug between gate patterns.

### DESCRIPTION OF RELATED ARTS

As semiconductor technology has improved, patterning technology for forming a pattern over a wafer has gradually improved. The recent patterning technology has become capable of forming a pattern under 80 nm over a wafer. In semiconductor technology capable of patterning under 80 nm, limitations have arisen with respect to an area where a contact plug is formed. In particular, it has become extremely difficult to stably form the contact plug disposed between gate patterns. Herein, the gate patterns compose transistors of a semiconductor device.

A gate pattern in a semiconductor device includes a gate insulation layer, a gate electrode, and a gate hard mask, stacked in sequential order. Herein, spacers are formed on sidewalls of the gate pattern. The sidewall spacers provide electrical insulation between the gate electrode and an adjacent conductive layer. Furthermore, the sidewall spacers function as an etch stop layer during a contact hole formation process for forming a contact plug.

As semiconductor technology has improved, more devices are integrated into a single semiconductor device. Thus, the size of each pattern composing the semiconductor device has decreased. In particular, the size of the gate pattern as well as the spacing distance between gate patterns has decreased. However, sidewall insulation layers, i.e., sidewall spacers, of the gate pattern are generally required to maintain a certain thickness in order to have the above mentioned insulation effect and function as an etch stop layer.

Therefore, it has become extremely difficult to stably form a contact plug between gate patterns, because the spacing distance between the gate patterns has decreased while the required thickness of the sidewall insulation layer is maintained. For example, while the sidewall insulation layers demanded in a device fabricated by the conventional 80 nm semiconductor process technology are generally required to be formed in an almost uniform thickness ranging from approximately 280 Å to approximately 300 Å, a spacing distance between the gate patterns is continuously decreasing.

The decrease in spacing distance between the gate patterns results in an increase in aspect ratio inside the contact hole for forming the contact plug between the gate patterns. Consequently, it has become difficult to completely bury an inter-layer insulation layer inside the contact hole during a subsequent process.

FIG. 1 is a cross-sectional view illustrating a conventional method for fabricating a semiconductor device.

As shown in FIG. 1, gate patterns are formed over a substrate 11. Herein, each of the gate patterns includes a gate insulation layer 12, a gate electrode 13, and a gate hard mask 14 formed in sequential order.

Details with respect to a formation method of an individual gate pattern are described hereinafter. The gate insulation layer 12 is formed over the substrate 11. Then, the gate electrode 13 and the gate hard mask 14 are sequentially formed over the gate insulation layer 12. Subsequently, a photoresist pattern, although not illustrated, is formed over the gate hard mask 14 in order to form the gate patterns. After the gate hard mask 14 is etched using the photoresist pattern as an etch mask, the photoresist pattern is removed. Furthermore, the gate electrode 13 and the gate insulation layer 12 are patterned in one process using the gate hard mask 14 as an etch mask.

Subsequently, a buffer oxide layer 15 for use in gate sidewall spacers is formed over the gate patterns, each including the gate insulation layer 12, the gate electrode 13, and the gate hard mask 14. A first nitride layer 16 is formed over the buffer oxide layer 15. Herein, the first nitride layer 16 functions as a first gate spacer. Next, a second nitride layer 17 is formed. Herein, the second nitride layer 17 functions as a second spacer.

Furthermore, the buffer oxide layer 15, the first nitride layer 16, and the second nitride layer 17 are selectively removed through a dry etching process, such that, spacers remain only on sidewalls of the gate pattern.

Herein, the spacers function as insulation between the gate electrode of the gate pattern and an adjacent conductive layer. In detail, the nitride layers are formed to protect the individual gate patterns during a contact hole formation process for forming a contact plug between the gate patterns. That is, the nitride layers function as an etch barrier during a contact hole etching process, which removes an insulation layer buried between the gate patterns. Herein, the nitride layers are formed and patterned twice because a desired thickness is difficult to obtain at once, due to formation characteristics of the nitride layers.

Also, the nitride layers are formed twice to improve characteristics of a metal oxide semiconductor (MOS) transistor including the gate patterns, when the semiconductor device is fabricated. One operational characteristic of a semiconductor device is a leakage current characteristic. The operational characteristics are improved when the leakage current characteristic of the MOS transistor is maximally decreased. By forming the nitride layers in a certain thickness over sidewalls of the gate patterns composing the MOS transistor, the leakage current characteristic of the MOS transistor can be improved. Thus, the nitride layers formed over the sidewalls of the gate patterns are formed in a sufficiently large thickness in order to improve the leakage current characteristic of the MOS transistor.

Moreover, a high concentration ion implantation process is performed to form source/drain regions 18 and 18A, using the gate pattern as an ion implantation barrier. Herein, the source/drain region 18A represents a lightly doped drain (LDD) region.

Next, an oxide-based inter-layer insulation layer 19 is formed over the above resulting substrate structure.

Herein, the inter-layer insulation layer 19 is formed using an oxide-based insulation layer. The oxide-based insulation layer can be formed of a borosilicate glass (BSG) layer, a boro-phospho-silicate glass (BPSG) layer, a phosphosilicate glass (PSG) layer, a tetraethyl orthosilicate (TEOS) layer, a high density plasma (HDP) oxide layer, a spin-on-glass (SOG) layer, and an advanced planarization layer (APL). Also, an inorganic or organic low-K dielectric layer can be used instead of the oxide-based layer.

Subsequently, a chemical mechanical polishing (CMP) process or a blanket etch-back process is performed to planarize the inter-layer insulation layer 19, exposing a top portion of the gate hard mask 14 of the gate pattern. Then, a hard mask, although not shown, is formed over the planarized inter-layer insulation layer 19.

Furthermore, an etching process for exposing a portion of the substrate 11 between the gate patterns using the hard mask as an etch mask is performed to form a contact hole 20.

The above-described conventional method for fabricating the semiconductor device often shows limitations as described below.

As semiconductor fabrication technology has improved, more devices are integrated into a single semiconductor device, and thus, the spacing distance between gate patterns has gradually decreased. However, spacers formed on sidewalls of each of the gate patterns are generally required to maintain a certain thickness in order to reduce deterioration of characteristics of the transistors including the gate patterns.

Thus, as the spacing distance between the gate patterns has decreased due to the increased integration, a margin in the etching process for forming the contact hole between the gate patterns with the spacers has gradually decreased.

When fabricating a semiconductor device under 80 nm, it has become often difficult to stably form the contact hole and the contact plug between the gate patterns while maintaining the necessary thickness of the gate spacers.

The contact plug formed between the gate patterns is generally an extremely basic conductive connection unit in a semiconductor device. If a semiconductor device is fabricated with an imperfect contact plug, it may be almost impossible for the device to stably operate.

### SUMMARY OF THE INVENTION

It is, therefore, an object of the present invention to provide a method for fabricating a semiconductor device, which can secure an open margin and a gap-fill margin of a contact hole formed between gate patterns.

In accordance with an aspect of the present invention, there is provided a method for fabricating a semiconductor device including: forming at least two gate patterns over a substrate; forming a first sidewall layer over on entire of the substrate structure including gat patterns; forming an insulation layer over the first sidewall layer; selectively removing the insulation layer between the gate patterns to form a contact hole partially exposing the first sidewall layer; forming a second sidewall layer over the first sidewall layer exposed by the contact hole; and removing the first and the second sidewall layers disposed at a bottom portion of the contact hole to expose a selected portion of the substrate between the gate patterns.

In accordance with another aspect of the present invention, there is provided a method for fabricating a semiconductor device including: forming at least two gate patterns over a substrate; forming a first spacer over sidewalls of the gate patterns; forming an insulation layer over the gate patterns; selectively removing the insulation layer between the gate patterns to form a contact hole exposing a portion of the substrate between the gate patterns; forming a spacer layer over the portion of the substrate and the first spacer exposed by the contact hole; and removing the spacer layer disposed at a bottom portion of the contact hole to form a second spacer over the first spacer.

In accordance with a further aspect of the present invention, there is provided a method for fabricating a semiconductor device including: forming at least two gate patterns over a substrate; forming a first sidewall layer over an entire of a substrate structure including the gate pattern; forming an auxiliary sidewall layer over the first sidewall layer; forming an insulation layer over the auxiliary sidewall layer; selectively removing the insulation layer between the gate patterns to form a contact hole partially exposing the auxiliary sidewall layer; forming a second sidewall layer over the auxiliary sidewall layer exposed by the contact hole; and removing the first sidewall layer, the auxiliary sidewall layer and the second sidewall layers disposed at a bottom portion of the contact hole to expose a portion of the substrate between the gate patterns.

In accordance with a further aspect of the present invention, there is provided a method for fabricating a semiconductor device including: forming at least two gate patterns over a substrate; forming a first spacer over sidewalls of the gate patterns; forming an auxiliary spacer over the first spacer; forming an insulation layer over the gate patterns; removing the insulation layer between the gate patterns to form a contact hole exposing a portion of the substrate between the gate patterns; forming a spacer layer over an inside of the contact hole; and removing the spacer layer disposed at a bottom portion of the contact hole to form a second spacer over the auxiliary spacer.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a conventional method for fabricating a semiconductor device;

FIGS. 2A to 2C are cross-sectional views illustrating a method for fabricating a semiconductor device in accordance with a first embodiment of the present invention;

FIGS. 3A to 3E are cross-sectional views illustrating a method for fabricating a semiconductor device in accordance with a second embodiment of the present invention; and

FIG. 4 is a micrograph of a scanning electron microscopy (SEM) image illustrating a contact hole area formed by employing a landing plug contact formation process in accordance with the second embodiment of the present invention.

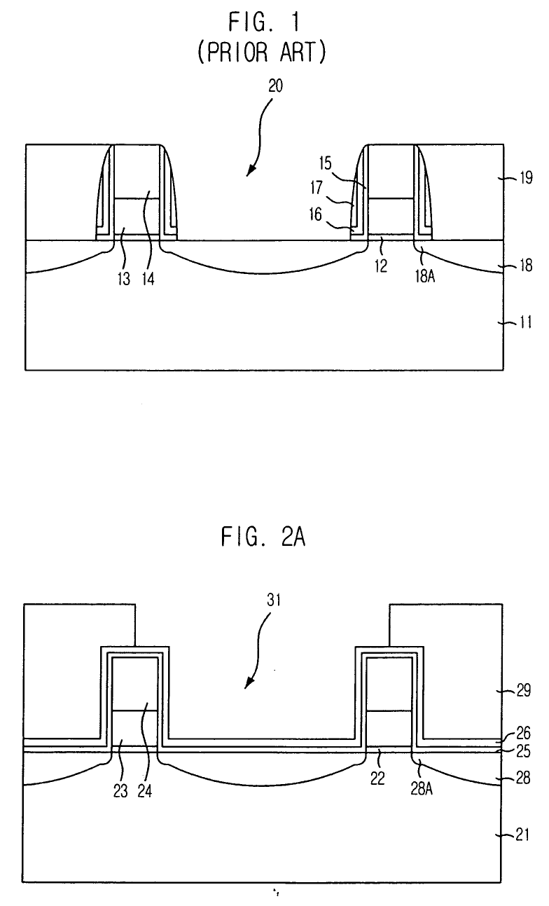

### DETAILED DESCRIPTION OF THE INVENTION

A method for fabricating a semiconductor device in accordance with an embodiment of the present invention includes forming at least two gate patterns over a substrate; forming a first sidewall layer over on entire of the substrate structure including gat patterns; forming an insulation layer over the first sidewall layer; selectively removing the insulation layer between the gate patterns to form a contact hole partially exposing the first sidewall layer; forming a second sidewall layer over the first sidewall layer exposed by the contact hole; and removing the first and the second sidewall layers disposed at a bottom portion of the contact hole to expose a selected portion of the substrate between the gate patterns.

A method for fabricating a semiconductor device in accordance with an another embodiment of the present invention includes forming at least two gate patterns over a substrate; forming a first spacer over sidewalls of the gate patterns; forming an insulation layer over the gate patterns; selectively removing the insulation layer between the gate patterns to form a contact hole exposing a portion of the substrate between the gate patterns; forming a spacer layer over the portion of the substrate and the first spacer exposed by the contact hole; and removing the spacer layer disposed at a bottom portion of the contact hole to form a second spacer over the first spacer.

A method for fabricating a semiconductor device in accordance with an another embodiment of the present invention includes forming a first sidewall layer over an entire of a substrate structure including the gate pattern; forming an auxiliary sidewall layer over the first sidewall layer; forming an insulation layer over the auxiliary sidewall layer; selectively removing the insulation layer between the gate patterns to form a contact hole partially exposing the auxiliary sidewall layer; forming a second sidewall layer over the auxiliary sidewall layer exposed by the contact hole; and removing the first sidewall layer, the auxiliary sidewall layer and the second sidewall layers disposed at a bottom portion of the contact hole to expose a portion of the substrate between the gate patterns.

A method for fabricating a semiconductor device in accordance with an another embodiment of the present invention includes forming at least two gate patterns over a substrate; forming a first spacer over sidewalls of the gate patterns; forming an auxiliary spacer over the first spacer; forming an insulation layer over the gate patterns; removing the insulation layer between the gate patterns to form a contact hole exposing a portion of the substrate between the gate patterns; forming a spacer layer over an inside of the contact hole; and removing the spacer layer disposed at a bottom portion of the contact hole to form a second spacer over the auxiliary spacer.

Hereinafter, detailed descriptions on certain embodiments of the present invention will be provided with reference to the accompanying drawings.

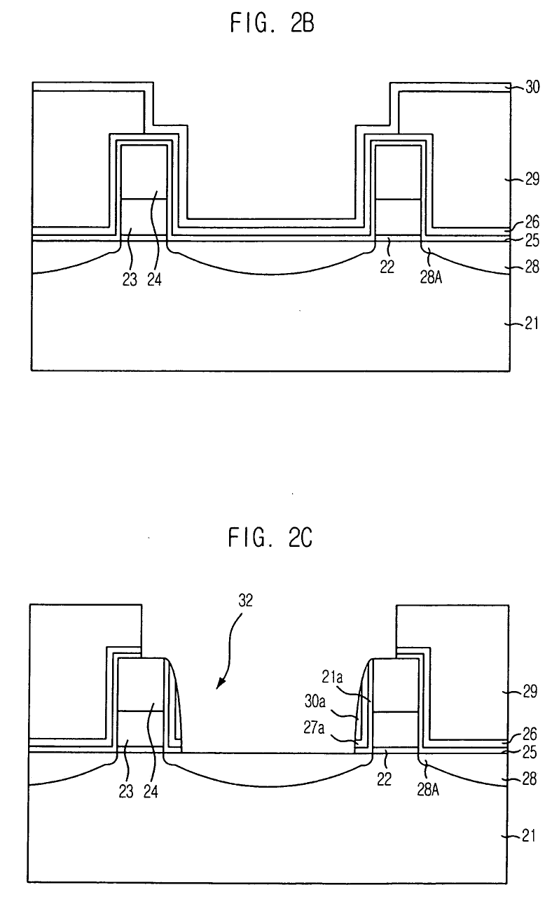

FIGS. 2A to 2C are cross-sectional views illustrating a method for fabricating a semiconductor device in accordance with a first embodiment of the present invention.

Referring to FIG. 2A, a plurality of gate patterns are formed over a substrate 21. Each of the gate patterns is formed by stacking a gate insulation layer 22, a gate electrode layer 23, and a gate hard mask 24 in sequential order.

In more detail about the forming of the gate patterns, the gate insulation layer 22 is formed over the substrate 21. The gate electrode layer 23 and the hard mask 24 are sequentially formed over the gate insulation layer 22. Although not illustrated, a photoresist pattern is formed over the gate hard mask 24. The gate hard mask 24 is etched using the photoresist pattern as an etch mask and then, the photoresist pattern is removed. The gate electrode layer 23 and the gate insulation layer 22 are patterned using the hard mask 24 as an etch mask through one etching process.

A highly doped ion-implantation process is performed using the gate patterns as an ion-implantation barrier, thereby forming a plurality of source/drain regions 28.

An oxide-based layer 25 and a first nitride-based layer 26 are sequentially formed over the gate patterns. The oxide based-layer 25 may be a buffer oxide layer. The oxide-based layer 25 and the first nitride-based layer may serve as a first gate spacer.

For the first nitride-based layer 26, a thickness of the first nitride-based layer 26 is determined by considering its role as an etch stop layer during a subsequent process and a formation of lightly doped drain (LDD) regions. Herein, the first nitride-based layer 26 may be formed in a thickness ranging from approximately 50 Å to approximately 250 Å. Preferably, the thickness of the first nitride-based layer 26 ranges from approximately 80 Å to approximately 120 Å.

Next, a plurality of LDD regions 28A are formed by performing a LDD ion-implantation process using the gate patterns as an ion-implantation barrier. An inter-layer insulation layer 29 is formed to bury the gate patterns. The inter-layer insulation layer 29 includes an oxide-based insulation layer. For instance, the oxide-based insulation layer may be one selected from the group consisting of a borosilicate glass (BSG) layer, a boro-phospho-silicate glass (BPSG) layer, a phosphosilicate glass (PSG) layer, a tetraethyl orthosilicate (TEOS) layer, a high density plasma (HDP) oxide layer, a spin-on-glass (SOG) layer, and an advanced planarization layer (APL). In addition to the oxide-based insulation layer, an inorganic or organic low-K dielectric layer can also be used.

Although not illustrated, a photoresist pattern is formed over the inter-layer insulation layer 29 to form a contact hole between the gate patterns. Because the contact hole to be formed is a self-aligned contact, the photoresist pattern has a width larger than the contact hole.

The inter-layer insulation layer 29 is selectively removed using the photoresist pattern as an etch barrier, thereby forming a first contact hole 31. The etching of the inter-layer insulation layer 29 is carried out using a characteristic that an oxide-based material and a nitride-based material has an etch selectivity. The inter-layer insulation layer 29 can be etched using a gas selected from a family of CₓF_{y}, where x and y representing atomic ratios ranges from approximately 1 to approximately 10. For instance, the CₓF_{y} based gas may be selected from the group consisting of C₄F₆, C₅F₈, C₄F₈, and C₃F₃. At this time, the first nitride-based layer 26 serves as an etch stop layer.

As illustrated, a portion of the first nitride-based layer 26 is exposed after the first contact hole 31 is formed. Although the photoresist pattern is formed to have a width larger than the contact hole, it is possible to form the contact hole with a desirable width because of the first nitride-based layer 26, which is formed over the gate patterns and serves as the etch stop layer.

In more detail, since the first contact hole 31 is formed under a state that the first nitride-based layer 26 is formed in a single layer through one process, the process of forming the first contact hole 31 is performed under a state that a distance between the gate patterns becomes wider than the distance which may be achieved by a conventional method. Accordingly, a sufficient margin can be secured. That is, compared with the conventional method, the distance between the gate patterns is increased to be about twice as large as the thickness of the first nitride-based layer 26.

Although not illustrated, an auxiliary nitride-based layer may be formed over the first nitride-based layer 26. The auxiliary nitride-based layer is formed more thinly than the first nitride-based layer 26 or a second nitride-based layer, which will be formed subsequently. For instance, the thickness of the auxiliary nitride-based layer may range from approximately 50 Å to approximately 150 Å. In the case that the inter-layer insulation layer 29 includes BPSG, the auxiliary nitride-based layer plays a role in reducing diffusion of impurities implanted onto the source/drain regions 28 (e.g., boron) into the substrate 21 during a thermal process. In other words, the auxiliary nitride-based layer functions as an auxiliary spacer.

Referring to FIG. 2B, a second nitride-based layer 30 is formed over the first contact hole 31. The second nitride-based layer 30 serves as a second spacer.

Herein, a thickness of the second nitride-based layer 30 is determined by considering the fact that a total thickness of the second nitride-based layer 30 and the first nitride-based layer 26 remaining after being used as an etch barrier for forming the contact hole 31 is larger than at least a certain value that does not allow an exposure of the gate patterns.

Furthermore, the thickness of the second nitride-based layer 30 is determined by considering the fact that a leakage current characteristic of a metal oxide semiconductor (MOS) transistor including the gate patterns determines a total thickness of the second nitride-based layer 30 and the first nitride-based layer 26 remaining after being used as the etch barrier for forming the contact hole 31.

Referring to FIG. 2C, an etching process is performed to remove the oxide-based layer 25, the first nitride-based layer 26, and the second nitride-based layer 30 disposed at a bottom portion of the first contact hole 31. Accordingly, a plurality of gate spacers are formed on sidewalls of the gate patterns. Each of the gate spacers includes a patterned second nitride-based layer 30A, a patterned first nitride-based layer 26A and a patterned buffer oxide-based layer 25A. Afterwards, a second contact hole 32 is opened.

As described above, the first gate spacer is first formed in a dual structure of an oxide-based layer and a nitride-based layer. Then, the contact hole is formed between the gate patterns, and using another nitride-based layer, the second gate spacer is formed thereafter. Thus, a distance between the gate patterns becomes wider when the contact hole is formed. Accordingly, an aspect ratio of the contact hole is greatly improved and thus, a subsequent process can be performed more easily.

Due to a decrease in aspect ratio of the contact hole between the gate patterns, an open margin of the contact hole between the gate patterns is increased greatly. Furthermore, due to the decreased aspect ratio, a gap-fill margin is also increased when the contact hole is filled with an inter-layer insulation layer. Accordingly, the contact hole can be formed stably between the gate patterns in semiconductor devices under approximately 80 nm.

The first embodiment of the present invention is not related to any particular kind of semiconductor devices and can be applied to various types of the semiconductor devices using a stack structure of an oxide-based layer (e.g., a silicon oxide layer) and a nitride-based layer (e.g., a silicon nitride layer) as a gate spacer.

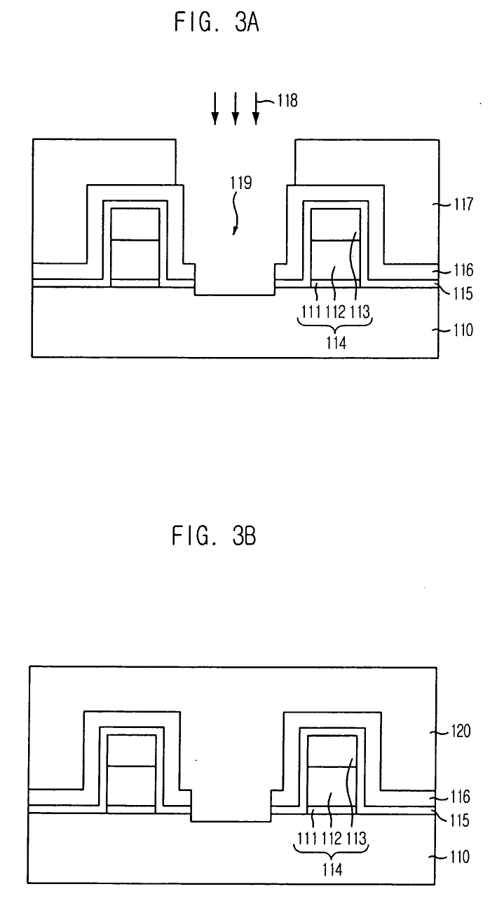

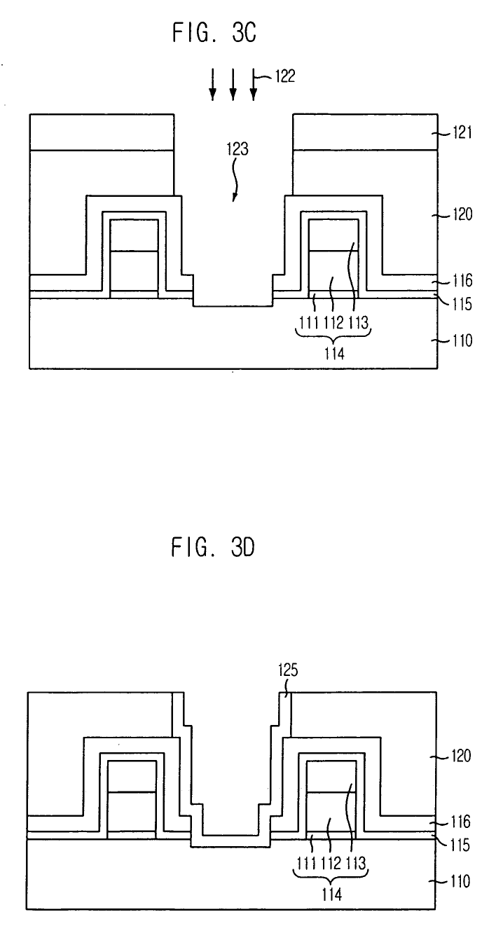

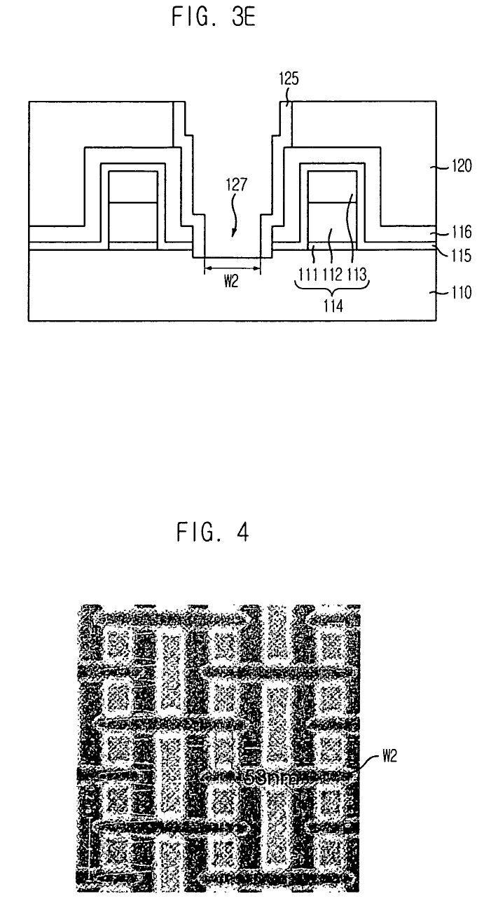

FIGS. 3A to 3E are cross-sectional views illustrating a method for fabricating a semiconductor device in accordance with a second embodiment of the present invention.

As shown in FIG. 3A, a plurality of gate patterns 114 are formed over a substrate 110 provided with device isolation layers (not shown) and wells (not shown). Each of the gate patterns 114 is formed by sequentially stacking a gate insulation layer 111, a gate electrode layer 112 and a gate hard mask 113. The gate insulation layer 111 includes a typical oxide-based layer such as a silicon oxide layer. The gate electrode layer 112 is formed by using one selected from the group consisting of conductive polysilicon, tungsten (W), tungsten nitride (WN), tungsten silicide (WSiₓ), and a combination thereof. Herein, x represents an atomic ratio of silicon to tungsten and is a positive number. Furthermore, the gate hard mask 113 serves a role in protecting the gate electrode layer 112 during a subsequent etching process for forming a contact plug between the gate patterns.

Accordingly, to form the contact plug between the gate patterns, a material having a different etch selectivity from a nitride layer is used. For instance, in the case of using an oxide-based layer as an insulation layer, a nitride-based material such as silicon nitride (SiN) or silicon oxynitride (SiON) can be used as the gate hard mask 113. In the case of using a polymer-based low-K dielectric layer, an oxide-based material is used as the hard mask 113.

Although not illustrated, an ion implantation process is performed to form source/drain junction regions in certain regions of the substrate 110 between the gate patterns 114.

Next, a selective oxide layer (not shown) and an oxide-based layer 115 (e.g., a buffer oxide layer) are formed over the gate patterns 114 and the substrate 110. A first nitride-based layer 116 is formed over the oxide-based layer 115. The oxide-based layer 115 and the first nitride-based layer 116 serve as a first spacer. The first nitride-based layer 116 is formed in a thickness ranging from approximately 50 Å to approximately 250 Å. Preferably, the thickness of the first nitride-based layer 116 ranges from approximately 120 Å to approximately 250 Å.

Although not illustrated, a photoresist layer is formed over the first nitride-based layer 116 and afterwards, a photoresist pattern 117 is formed by performing a photo-exposure process and a developing process using a photo-mask (not shown).

A first etching process 118 using the photoresist pattern 117 as an etch mask is performed, thereby removing the first nitride-based layer 116 and the buffer oxide-based layer 115 between the gate patterns 114. As a result, an opening 119 (e.g. a contact hole) exposing a portion of the substrate 110 between the gate patterns 114 is formed. The exposed portion of the substrate region may be the source/drain junction region. Herein, the first etching process 118 is performed using one gas selected from the group consisting of CₓF_{y}, where x and y representing atomic ratios ranges from approximately 1 to approximately 10, CHF₃, Ar, O₂, and CO.

Although not illustrated, an auxiliary nitride-based layer may be formed over the first nitride-based layer 116. The auxiliary nitride-based layer is formed more thinly than the first nitride-based layer 116 or a second nitride-based layer, which will be formed subsequently. For instance, the thickness of the auxiliary nitride-based layer may range from approximately 50 Å to approximately 150 Å. Preferably, the thickness of the auxiliary nitride-based layer ranges from approximately 80 Å to approximately 120 Å. In the case that the inter-layer insulation layer 120 includes BPSG, the auxiliary nitride-based layer plays a role in reducing diffusion of impurities implanted onto the source/drain junction regions (e.g., boron) into the substrate 21 during a thermal process. In other words, the auxiliary nitride-based layer functions as an auxiliary spacer.

Referring to FIG. 3B, a stripping process is performed, to remove the photoresist pattern 117. An inter-layer insulation layer 120 is formed to bury the gate patterns 114. Herein, the inter-layer insulation layer 120 includes an oxide-based material such as silicon oxide. For instance, the inter-layer insulation layer 120 is one selected from the group consisting of a high density plasma (HDP) oxide layer, a borophosphosilicate glass (BPSG) layer, a phosphosilicate glass (PSG) layer, a plasma enhanced tetraethyl orthosilicate (PETEOS) layer, a plasma enhanced chemical vapor deposition (PECVD) layer, a undoped silicate glass (USG) layer, a fluorinated silicate glass (FSG) layer, a carbon doped oxide (CDO) layer, an organic silicate glass (OSG), layer and a combination thereof.

With reference to FIG. 3C, although not illustrated, a photoresist layer is formed over the inter-layer insulation layer 120. Afterwards, a photo-exposure process and a developing process using a photo-mask (not shown) are performed to form a photoresist pattern 121.

A second etching process 122 is performed using the photoresist pattern 121 as an etch mask to etch the inter-layer insulation layer 120. Particularly, the second etching process is performed to expose the portion of the substrate 110 between the gate patterns 114. As a result, another opening 123 (e.g. a contact hole) exposing the aforementioned source/drain junction region (not shown) is formed. Herein, the second etching process 122 is performed using a gas selected from a family of CₓF_{y}, where x and y representing atomic ratios range from approximately 1 to approximately 10. For instance, the family of CₓF_{y} gas may include C₄F₆, C₅F₈, C₄F₈, and C₃F₃. During the second etching process 122, the first nitride-based layer 116 serves a role in protecting the gate patterns 114.

Furthermore, the second etching process 122 may use a hard mask. For instance, although not illustrated, the hard mask may include a nitride-based material, amorphous carbon, or polysilicon, and is formed using the photoresist pattern 121, which is subsequently removed via a stripping process. Afterwards, the second etching process 122 may be performed using a remaining portion of the hard mask as an etch barrier.

Referring to FIG. 3D, the photoresist pattern 121 is removed by performing a stripping process. A second nitride-based layer 125 is formed over the patterned inter-layer insulation layer 120. A chemical mechanical polishing (CMP) process is performed on the second nitride-based layer 125 such that the second nitride-based layer 125 remains only inside the other opening 123 (i.e., sidewalls of the patterned inter-layer insulation layer 120). The second nitride-based layer 125 serves as a second spacer.

A thickness of the second nitride-based layer 125 is determined by considering the fact that a total thickness of the second nitride-based layer 125 and the first nitride-based layer 116 is larger than at least a certain value that does not allow an exposure of the gate patterns 114.

Furthermore, the thickness of the second nitride-based layer 125 is determined by considering the fact that a leakage current characteristic of a metal oxide semiconductor (MOS) transistor including the gate patterns 114 determines a total thickness of the second nitride-based layer 125 and the first nitride-based layer 116 remaining after being used as the etch barrier for forming the openings 119 and 123. It is illustrated in the second embodiment that the second nitride-based layer 125 is formed apart from the first nitride-based layer 116 by having the inter-layer insulation layer 120 in between the first nitride-based layer 116 and the second nitride-based layer 125. However, it is still possible to form the second nitride-based layer 125 in contact with the first nitride-based layer 116.

Referring to FIG. 3E, an etch-back process is performed to remove the second nitride-based layer 125 disposed at a bottom portion of the other opening 123. As a result, the portion of the substrate 110 between the gate patterns 114 becomes exposed, defining a further opening 127 (e.g., a contact hole) Although not shown, a conductive material fills the further opening 127 (e.g., a contact hole), thereby forming a contact plug.

FIG. 4 is a micrograph of a scanning electron microscopy (SEM) image illustrating a contact hole area formed by a contact hole formation process in accordance with the second embodiment of the present invention.

As illustrated, the area W₂ of the contact hole formed according to the second embodiment is approximately 53 nm. Compared with an area of a conventional contact hole, which is approximately 24 nm, the area W₂ of the contact hole according to the second embodiment is increased by approximately 19 nm. Hence, an aspect ratio of the contact hole is also increased. As mentioned previously, the conventional contact hole has an aspect ratio of 16.3 to 1. On the contrary, the aspect ratio of the contact hole according to the second embodiment is approximately 8.6 to 1.

On the basis of the exemplary embodiments of the present invention, a contact hole, which opens a source/drain region, is formed after a first nitride-based layer is formed. Afterwards, an inter-layer insulation layer is formed to be filled within the contact hole. As a result, a margin for forming a contact hole is increased, resulting in formation of the contact hole wider than the conventional contact hole. This fact indicates that a gap-fill margin for the inter-layer insulation layer is secured.

More specifically, in the conventional method, the inter-layer insulation layer is formed after the first nitride and second nitride layers, which serve as first and second gate spacers, respectively, are formed. Thus, a distance between gate patterns is not sufficient, causing a decrease in the gap-fill margin for the inter-layer insulation layer. However, according to the exemplary embodiments of the present invention, the inter-layer insulation layer is formed after the first nitride-based layer, which serves as the first gate spacer, is formed. As a result, a distance between the gate patterns is increased. Thus, a gap-fill margin for the inter-layer insulation layer can be secured. Securing the gap-fill margin indicates that an aspect ratio of the contact hole can be reduced. Accordingly, an incidence that a contact hole is not opened or is opened improperly is less likely to occur.

As described above, an aspect ratio of a contact hole can be improved through sequential steps. First, a gate spacer is formed in double layers of an oxide-based layer (e.g., a buffer oxide layer) and a nitride-based layer (e.g. a silicon nitride layer). Then, an etching process for forming a landing plug contact is formed. Another nitride-based layer, which serves as a gate spacer, is formed. By improving the aspect ratio of the contact hole, a process margin can also be improved.

Because of the reduction in the aspect ratio, a margin for opening an oxide-based layer using a self-aligned contact (SAC) method can be increased. As a result, a sufficient open margin can be secured in sub-80 nm devices. Also, the reduction in the aspect ratio can provided an effect of improving a gap-fill margin for an inter-layer insulation layer.

The present application contains subject matter related to the Korean patent application nos. KR 2005-0016845, KR 2005-0051372 and KR 2006-0016820, filed in the Korean Patent Office on Feb. 28, 2005, Jun. 15, 2005 and Feb. 21, 2006, respectively, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device comprising:
forming at least two gate patterns over a substrate;
forming a first sidewall layer over on entire of the substrate structure including gat patterns;
forming an insulation layer over the first sidewall layer;
selectively removing the insulation layer between the gate patterns to form a contact hole partially exposing the first sidewall layer;
forming a second sidewall layer over the first sidewall layer exposed by the contact hole; and
removing the first and the second sidewall layers disposed at a bottom portion of the contact hole to expose a selected portion of the substrate between the gate patterns.

2. The method of claim 1, wherein a total thickness of the first and the second sidewall layers is larger than a predetermined value that reduces damage to the gate patterns during a subsequent process.

3. The method of claim 1, wherein a total thickness of the first and the second sidewall layers is determined by a level of leakage current from metal oxide semiconductor (MOS) transistors including the gate patterns, respectively.

4. The method of claim 1, wherein the selectively removing the insulation layer includes:
forming a photoresist pattern over the insulation layer, the photoresist pattern having a width larger than the contact hole to be formed; and
selectively removing the insulation layer by using the photoresist pattern as an etch barrier to form the contact hole.

5. The method of claim 1, wherein the first sidewall layer and the second sidewall layer include a nitride-based insulation layer, wherein the nitride-based insulation layer includes silicon nitride.

6. The method of claim 5, wherein the insulation layer includes an oxide-based insulation layer, wherein the oxide-based insulation layer includes silicon oxide.

7. The method of claim 1, further comprising performing an ion implantation process at a predetermined region of the substrate to form a junction region.

8. The method of claim 4, wherein the first sidewall insulation layer has a thickness ranging from approximately 50 Å to approximately 250 Å.

9. The method of claim 1, wherein the selective removing of the insulation layer between the gate patterns comprises using a gas selected from a family of CₓF_{y}, where x and y representing atomic ratios is in a range between approximately 1 and approximately 10.

10. The method of claim 1, wherein the selective removing of the insulation layer between the gate patterns comprises using a gas selected from the group consisting of C₄F₆, C₅F₈, C₄F₈ and C₃F₃.

11. The method of claim 1, wherein the first sidewall layer includes a silicon nitride layer and a silicon oxide layer.

12. A method for fabricating a semiconductor device comprising:
forming at least two gate patterns over a substrate;
forming a first spacer over sidewalls of the gate patterns;
forming an insulation layer over the gate patterns;
selectively removing the insulation layer between the gate patterns to form a contact hole exposing a portion of the substrate between the gate patterns;
forming a spacer layer over the portion of the substrate and the first spacer exposed by the contact hole; and
removing the spacer layer disposed at a bottom portion of the contact hole to form a second spacer over the first spacer.

13. The method of claim 12, wherein the first and second spacers have a total thickness larger than a predetermined value that reduces damage to the gate patterns during a subsequent process.

14. The method of claim 12, wherein a total thickness of the first and the second spacers is determined by a level of leakage current from metal oxide semiconductor (MOS) transistors including the gate patterns, respectively.

15. The method of claim 12, wherein the selectively removing the insulation layer includes:
forming a photoresist pattern over the insulation layer, the photoresist pattern having a width larger than the contact hole to be formed; and
selectively removing the insulation layer by using the photoresist pattern as an etch barrier to form the contact hole.

16. The method of claim 12, wherein each of the first spacer and the second spacer includes a nitride-based insulation layer, wherein the nitride-based insulation layer includes silicon nitride.

17. The method of claim 16, wherein the insulation layer includes an oxide-based insulation layer, wherein the oxide-based insulation layer includes silicon oxide.

18. The method of claim 12, further comprising performing an ion implantation process at a predetermined region of the substrate to form a junction region.

19. The method of claim 17, wherein the first spacer has a thickness ranging from approximately 50 Å to approximately 250 Å.

20. The method of claim 12, wherein the selective removing of the insulation layer between the gate patterns comprises a gas selected from a family of CₓF_{y}, where x and y representing atomic ratios are in a range between approximately 1 and approximately 10.

21. The method of claim 12, wherein the selective removing of the insulation layer between the gate patterns comprises using a gas selected from the group consisting of C₄F₆, C₅F₈, C₄F₈ and C₃F₃.

22. The method of claim 12, wherein each of the gate patterns includes a silicon nitride layer and a silicon oxide layer.

23. The method of claim 14, wherein the forming of the first spacer comprises using a gas selected from the group consisting of CₓF_{y}, where x and y representing atomic ratios is in a range between approximately 1 and approximately 10, CHF₃, Ar, O₂ and CO.

24. A method for fabricating a semiconductor device comprising:
forming at least two gate patterns over a substrate;
forming a first sidewall layer over an entire of a substrate structure including the gate pattern;
forming an auxiliary sidewall layer over the first sidewall layer;
forming an insulation layer over the auxiliary sidewall layer;
selectively removing the insulation layer between the gate patterns to form a contact hole partially exposing the auxiliary sidewall layer;
forming a second sidewall layer over the auxiliary sidewall layer exposed by the contact hole; and
removing the first sidewall layer, the auxiliary sidewall layer and the second sidewall layers disposed at a bottom portion of the contact hole to expose a portion of the substrate between the gate patterns.

25. The method of claim 24, wherein a total thickness of the first and the second sidewall layers is larger than a predetermined value that reduces damage to the gate patterns during a subsequent process.

26. The method of claim 24, wherein a total thickness of the first and the second sidewall layers is determined by a level of leakage current from metal oxide semiconductor (MOS) transistors including the gate patterns, respectively.

27. The method of claim 24, wherein the selectively removing the insulation layer includes:
forming a photoresist pattern over the insulation layer, the photoresist pattern having a width larger than the contact hole to be formed; and
selectively removing the insulation layer by using the photoresist pattern as an etch barrier to form the contact hole.

28. The method of claim 24, wherein each of the first sidewall layer and the second sidewall layer includes a nitride-based insulation layer, wherein the nitride-based insulation layer includes silicon nitride.

29. The method of claim 24, wherein the insulation layer includes an oxide-based insulation layer, wherein the oxide-based insulation layer includes silicon oxide.

30. The method of claim 24, further comprising performing an ion implantation process at a predetermined region of the substrate to form a junction region.

31. The method of claim 28, wherein the first sidewall insulation layer has a thickness ranging from approximately 50 Å to approximately 250 Å.

32. The method of claim 28, wherein the selective removing of the insulation layer between the gate patterns comprises using a gas selected from a family of CₓF_{y}, where x and y representing atomic ratios is in a range between approximately 1 and approximately 10.

33. The method of claim 24, wherein the selective removing of the insulation layer between the gate patterns comprises using a gas selected from the group consisting of C₄F₆, C₅F₈, C₄F₈ and C₃F₃.

34. The method of claim 24, wherein the first sidewall layer includes a silicon nitride layer and a silicon oxide layer.

35. The method of claim 24, wherein the auxiliary sidewall layer serves a role in reducing diffusion of impurities implanted onto the substrate.

36. The method of claim 35, wherein the auxiliary sidewall layer includes a nitride-based insulation layer, wherein the nitride-based insulation layer includes silicon nitride.

37. The method of claim 35, wherein the auxiliary sidewall layer is formed to a thickness ranging from approximately 50 Å to approximately 150 Å.

38. A method for fabricating a semiconductor device comprising:
forming at least two gate patterns over a substrate;
forming a first spacer over sidewalls of the gate patterns;
forming an auxiliary spacer over the first spacer;
forming an insulation layer over the gate patterns;
removing the insulation layer between the gate patterns to form a contact hole exposing a portion of the substrate between the gate patterns;
forming a spacer layer over an inside of the contact hole; and
removing the spacer layer disposed at a bottom portion of the contact hole to form a second spacer over the auxiliary spacer.

39. The method of claim 38, wherein the first and the second spacers have a total thickness larger than a predetermined value that reduces damage to the gate patterns during a subsequent process.

40. The method of claim 38, wherein a total thickness of the first and the second spacers is determined by a level of leakage current from metal oxide semiconductor (MOS) transistors including the gate patterns, respectively.

41. The method of claim 38, wherein the selectively removing the insulation layer includes:
forming a photoresist pattern over the insulation layer, the photoresist pattern having a width larger than the contact hole to be formed; and
selectively removing the insulation layer by using the photoresist pattern as an etch barrier to form the contact hole.

42. The method of claim 38, wherein the first spacer and the second spacer include a nitride-based insulation layer, wherein the nitride-based insulation layer includes silicon nitride.

43. The method of claim 42, wherein the insulation layer includes an oxide-based insulation layer, wherein the oxide-based insulation layer includes silicon oxide.

44. The method of claim 38, further comprising performing an ion implantation process at a predetermined region of the substrate to form a junction region.

45. The method of claim 44, wherein the first spacer has a thickness ranging from approximately 50 Å to approximately 250 Å.

46. The method of claim 38, wherein the selective removing of the insulation layer between the gate patterns comprises a gas selected from a family of CₓF_{y}, where x and y representing atomic ratios is in a range between approximately 1 and approximately 10.

47. The method of claim 38, wherein the selective removing of the insulation layer between the gate patterns comprises using a gas selected from the group consisting of C₄F₆, C₅F₈, C₄F₈ and C₃F₃.

48. The method of claim 38, wherein each of the gate patterns include a silicon nitride layer and a silicon oxide layer.

49. The method of claim 38, wherein the forming of the first spacer comprises using a gas selected from the group consisting of CₓF_{y}, where x and y representing atomic ratios is in a range between approximately 1 and approximately 10, CHF₃, Ar, O₂ and CO.

50. The method of claim 38, wherein the auxiliary sidewall layer serves a role in reducing diffusion of impurities implanted onto the substrate.

51. The method of claim 45, wherein the auxiliary sidewall layer includes a nitride-based insulation layer, wherein the nitride-based insulation layer includes silicon nitride.

52. The method of claim 45, wherein the auxiliary sidewall layer is formed to a thickness ranging from approximately 50 Å to approximately 150 Å.
